(19) United States
(12) Patent Application Publication
(10) Pub. No.: US 2026/0324434 A1
(43) Pub. Date: Oct. 15, 2026

(54) SUBSTRATE AND MANUFACTURING METHOD THEREOF

(71) Applicant: Unimicron Technology Corp., Taoyuan City (TW)

(72) Inventors: Po-Wen Hsiao, Taoyuan City (TW); Tzu-Chieh Peng, Taoyuan City (TW); Chia-Fu Hsu, Taichung City (TW); Tzyy-Jang Tseng, Taoyuan City (TW)

(73) Assignee: Unimicron Technology Corp., Taoyuan City (TW)

(21) Appl. No.: 19/632,421

(22) Filed: Mar. 30, 2026

Related U.S. Application Data
(60) Provisional application No. 63/786,995, filed on Apr. 11, 2025.

(51) Int. Cl. H10W 42/00; H10W 70/05; H10W 70/685; H10W 70/692

(52) U.S. Cl. CPC H10W 42/121; H10W 70/096; H10W 70/685; H10W 70/692

(57) ABSTRACT

A substrate includes a glass core circuit structure, a first cover layer and a first build-up structure. The glass core circuit structure includes a glass block and a vertical conductive connector. The first cover layer is embedded in the glass core circuit structure. The first build-up structure is disposed on and electrically connected to the glass core circuit structure. The first build-up structure includes a first insulating layer, and a Young’s modulus of the first cover layer is less than a Young’s modulus of the first insulating layer. A manufacturing method of a substrate is also provided.

### CROSS-REFERENCE TO RELATED APPLICATION

This application claims the priority benefit of the U.S. provisional application serial no. 63/786,995, filed on Apr. 11, 2025. The entirety of the above-mentioned patent application is hereby incorporated by reference herein and made a part of this specification.

### BACKGROUND

### Technical Field

The present disclosure relates to a substrate and a manufacturing method thereof.

### Description of Related Art

At present, a glass core substrate is widely applied to a high-order demand substrate due to their advantages of tunable modulus and CTE closer to silicon, dimensional stability, high through-hole density, ultra-low loss dielectric, smooth copper layer, and higher temperature capability. However, based on brittleness of the glass, stress produced in a conventional substrate manufacturing process may easy to lead to a crack (SeWaRe) issue, such that reliability of the glass core substrate may be reduced.

### SUMMARY

A substrate includes a glass core circuit structure, a first cover layer and a first build-up structure. The glass core circuit structure includes a glass block and a vertical conductive connector. The first cover layer is embedded in the glass core circuit structure. The first build-up structure is disposed on and electrically connected to the glass core circuit structure. The first build-up structure includes a first insulating layer, and a Young’s modulus of the first cover layer is less than a Young’s modulus of the first insulating layer.

A manufacturing method of a substrate includes providing a plurality of glass core circuit structures, wherein a dicing region is formed by a glass block portion located between adjacent glass core circuit structures; removing a portion of the glass block portion to form a trench; forming a cover layer in the trench; forming a build-up structure on the plurality of glass core circuit structures, wherein the build-up structure is electrically connected to the glass core circuit structures, and a Young’s modulus of the cover layer is less than a Young’s modulus of an insulating layer of the build-up structure; and performing a singulation process on the dicing region to form the substrate comprising one of the glass core circuit structures, a portion of the cover layer, and a portion of the build-up structure.

Based on the above, by designing the Young’s modulus and position of the introduced the cover layer, the stress generated during the manufacturing process can be effectively alleviated, thereby the crack (SeWaRe) issue of the glass block of the glass core circuit structure may be improved.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic cross-sectional view of a substrate according to some embodiments of the disclosure.

FIGS. 2-8 are partial schematic cross-sectional views of the substrate in FIG. 1 during different stages of a manufacturing process.

FIGS. 9-10 are partial schematic cross-sectional views of alternative embodiments during intermediate stages of a manufacturing process.

FIG. 11 is a schematic cross-sectional view of a substrate according to some embodiments of the disclosure.

FIGS. 12-18 are partial schematic cross-sectional views of the substrate in FIG. 1 during different stages of a manufacturing process.

FIG. 19 is a schematic cross-sectional view of a substrate according to some embodiments of the disclosure.

FIGS. 20-23 are partial schematic cross-sectional views of the substrate in FIG. 1 during different stages of a manufacturing process.

### DESCRIPTION OF THE EMBODIMENTS

In the detailed description of the embodiments, the terms, like "first", "second", and "third", may be used for describing different elements. The terms are merely used for distinguishing between the elements, but these elements should not be limited by these terms in a structure. For example, a first element may be referred to as a second element, moreover, similarly, the second element may be referred to as the first element without departing from the protection scope of the ideas of the disclosure. In addition, in the manufacturing method, the formation sequence of the elements or components should also not be limited by these terms except specific manufacturing processes. For example, the first element may be formed before the second element, or the first element may be formed after the second element, or the first element and the second element may be formed in the same process or step.

In addition, the thickness of films and regions in the drawings may be enlarged for clarity. The same or similar reference numbers are used for representing the same or similar components, and details are not described below again.

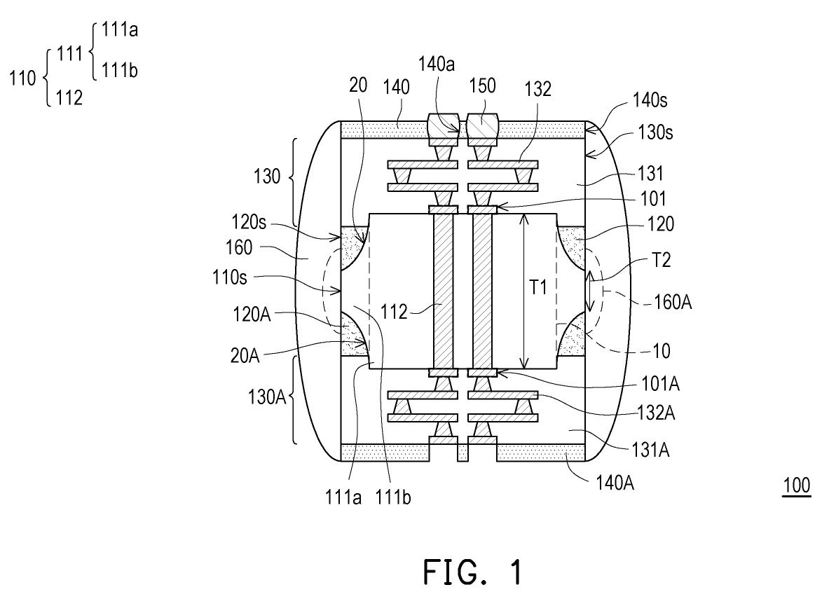

Referring to FIG. 1, a substrate 100 includes a glass core circuit structure 110, a cover layer 120 and a build-up structure 130, wherein the cover layer 120 is embedded in the glass core circuit structure 110 and the build-up structure 130 is disposed on and electrically connected to the glass core circuit structure 110. For example, the glass core circuit structure 110 includes a glass block 111 and vertical conductive connectors 112 penetrated through the glass block 111, the build-up structure 130 includes insulating layers 131 and conductive layers 132 embedded in the insulating layers 131, while a Young’s modulus of the cover layer 120 is less than a Young’s modulus of the insulating layer 131. Accordingly, by designing the Young’s modulus and position of the introduced the cover layer 120, the stress generated during the manufacturing process can be effectively alleviated, thereby the crack (SeWaRe) issue (such as horizontal crack propagation) of the glass block 111 of the glass core circuit structure 110 may be improved. Here, the vertical conductive connectors 112 may be TGVs. In addition, the vertical conductive connectors 112 may be full filled type or conformal type based on design requirement.

In FIG. 1, the glass block 111 includes two portions (divided by dashed line 10), such as a glass block portion 111a and a glass block portion 111b, wherein a thickness T1 of the glass block portion 111a is greater than a thickness T2 of the glass block portion 111b. For example, the glass block portion 111b has a tapered profile in a direction away from the glass block portion 111a, that is to say, the thickness T2 of the glass block portion 111b is the minimum thickness of the glass block portion 111b. In this configuration, the glass core circuit structure 110 may include a trench 20. In the embodiment, the trench 20 is filled by the cover layer 120, thereby the cover layer 120 may be in direct contact with the insulating layer 131 and the glass core circuit structure 110. Furthermore, the cover layer 120 may be disposed in the trench 20 only, and the insulating layer 131 may extend into a remained space of the trench 20.

In some embodiments, the substrate 100 is single element after being diced, such that a sidewall 120s of the cover layer 120 may be aligned with a sidewall 110s of the glass core circuit structure 110 (such as a sidewall of the glass block portion 111b), that is to say, the sidewall 120s of the cover layer 120 and the sidewall 110s of the glass core circuit structure 110 may be located at the substantial same position in a vertical direction.

In FIG. 1, the substrate 100 may further include a conductive pattern 101 landed on the glass block 111 and the vertical conductive connectors 112, that is to say, the conductive pattern 101 is in direct contact with the glass block 111 and the vertical conductive connectors 112, and the conductive pattern 101 may be electrically connected to the vertical conductive connectors 112 directly (no additional conductive vias are used).

Moreover, the substrate 100 may further include a resist layer 140 and bumps 150. To be specific, the resist layer 140 includes openings 140a to expose a topmost conductive layer 132 of the build-up structure 130, such that the bumps 150 may disposed in the openings 140a to touch the topmost conductive layer 132 to form conductive paths.

In an alternative embodiment, the substrate 100 may further include a cover layer 160 disposed on the sidewall 120s of the cover layer 120, the sidewall 110s of the glass core circuit structure 110, a sidewall 130s of the build-up structure 130, and a sidewall 140s of the resist layer 140, wherein a Young’s modulus of the cover layer 160 is greater than or equal to the Young’s modulus of the cover layer 120 to further provide protection function. In another alternative embodiment, the cover layer 160 may be replaced by a cover layer 160A disposed on the sidewall 120s of the cover layer 120 and the sidewall 110s of the glass core circuit structure 110 only (as shown on another dashed line), while the sidewall 130s of the build-up structure 130 and a sidewall 140s of the resist layer 140 may be exposed by the cover layer 160A.

In FIG. 1, the substrate 100 is an approximate symmetric structure, such that the substrate 100 may further include a trench 20A, a conductive pattern 101A, a cover layer 120A, a build-up structure 130A (including the insulating layers 131A and the conductive layers 132A) and a resist layer 140A as shown in the lower part of FIG. 1, such that implementation details of the trench 20A, the conductive pattern 101A, the cover layer 120A, the build-up structure 130A (including the insulating layers 131A and the conductive layers 132A) and the resist layer 140A may be referred to above description of the trench 20, the conductive pattern 101, the cover layer 120, the build-up structure 130 (including the insulating layers 131 and the conductive layers 132) and the resist layer 140 respectively. For example, the trench 20A, the conductive pattern 101A, the cover layer 120A, the build-up structure 130A (including the insulating layers 131A and the conductive layers 132A) and the resist layer 140A may be same as or similar to the trench 20, the conductive pattern 101, the cover layer 120, the build-up structure 130 (including the insulating layers 131 and the conductive layers 132) and the resist layer 140 respectively. Here, the bumps 150 may be formed on one side merely.

In this approximate symmetric structure, the build-up structure 130A is disposed on a surface opposite to the build-up structure 130 of the glass core circuit structure 110, the build-up structure 130 is electrically connected to the build-up structure 130A through the glass core circuit structure 110 (such as through the conductive pattern 101, the vertical conductive connectors 112 and the conductive pattern 101A), wherein the build-up structure 130A includes insulating layers 131A and conductive layers 132A embedded in the insulating layers 131A, and the Young’s modulus of the cover layer 120A is less than a Young’s modulus of the insulating layers 131A. The above description may be applied here, and will not be repeated.

It should be noted that the approximate symmetric structure in FIG. 1 for illustrative purposes only, the disclosure is not limited thereto, as long as the substrate includes at least one cover layer embedded in the glass core circuit structure, and the cover layer has corresponding design rules with the insulating layer of the build-up structure, it falls within the scope of protection of present disclosure.

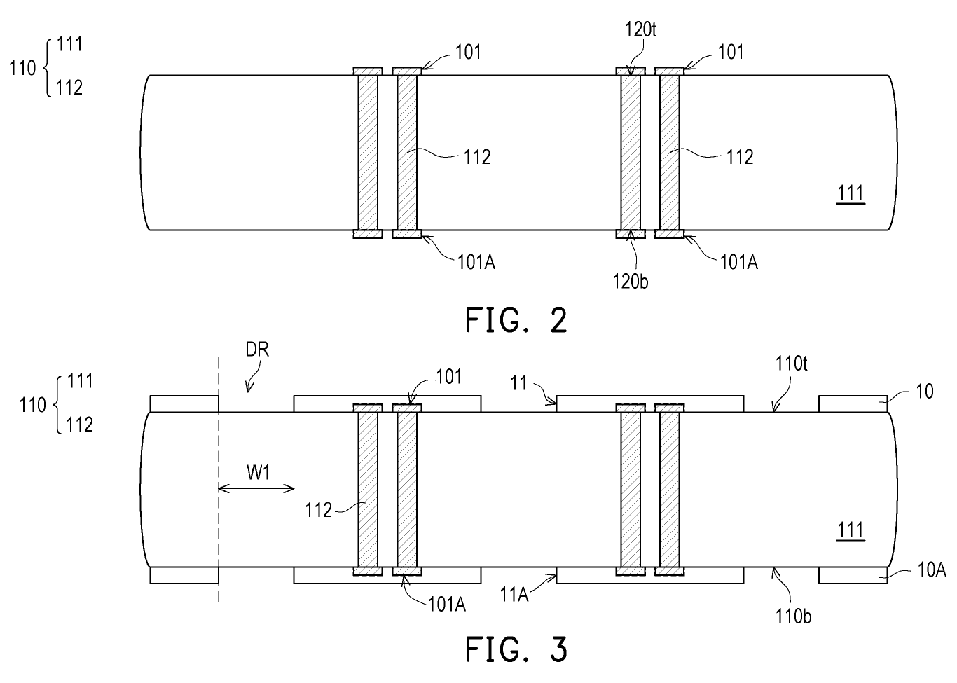

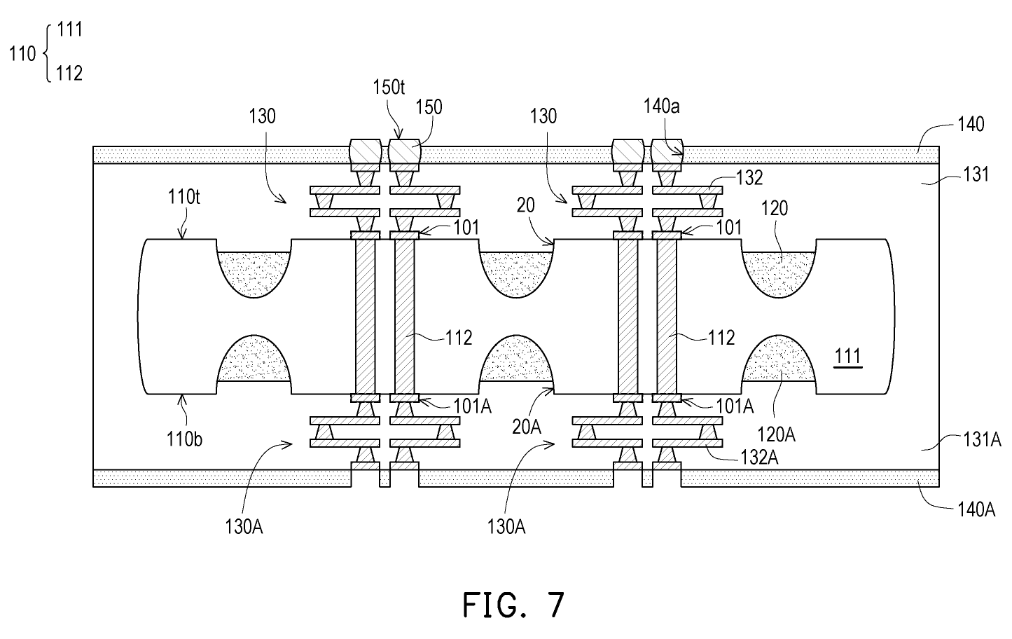

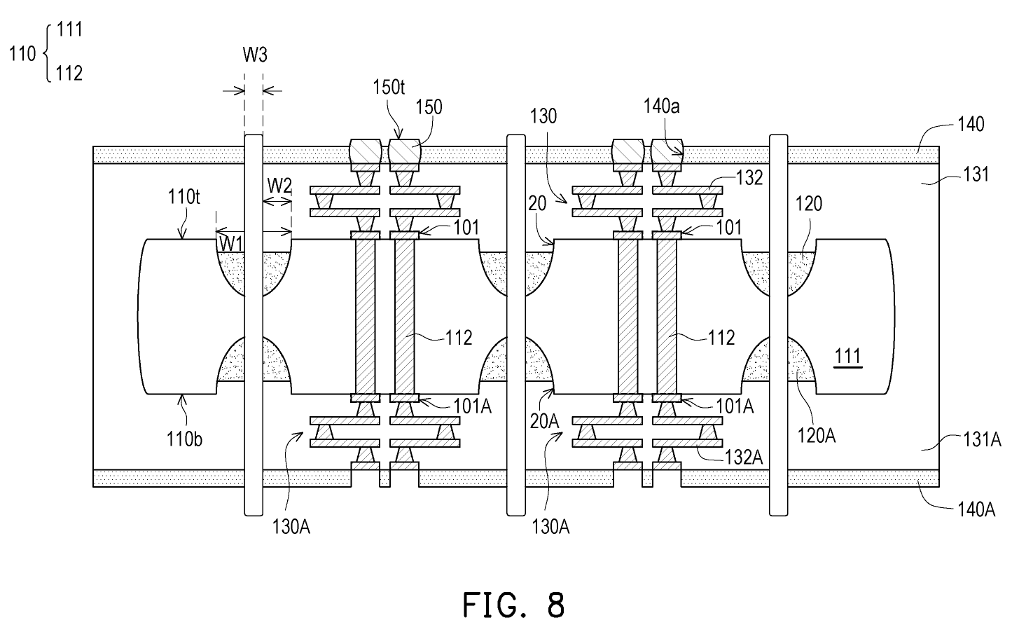

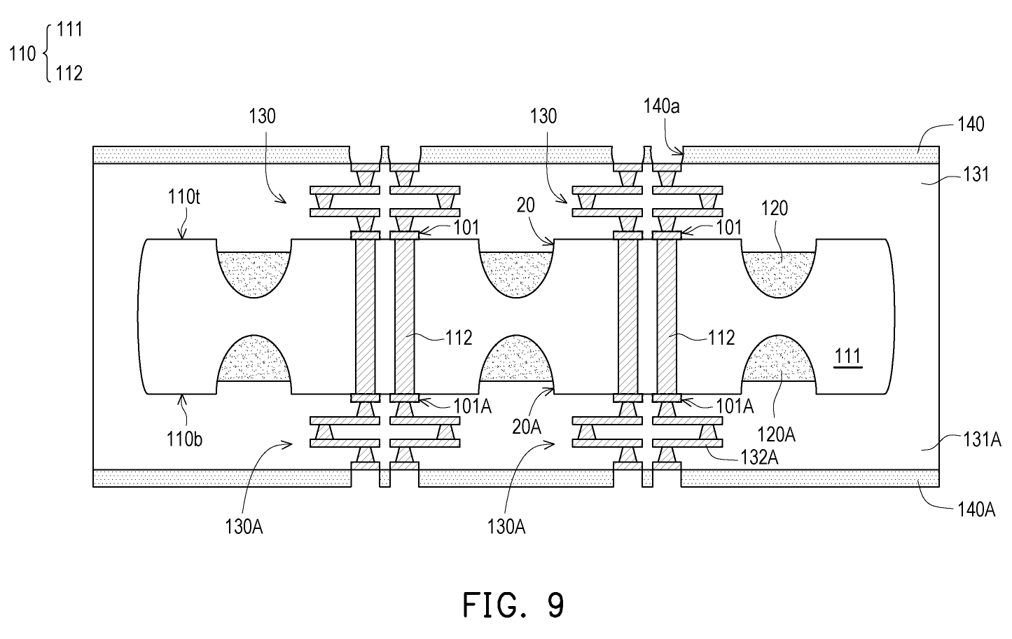

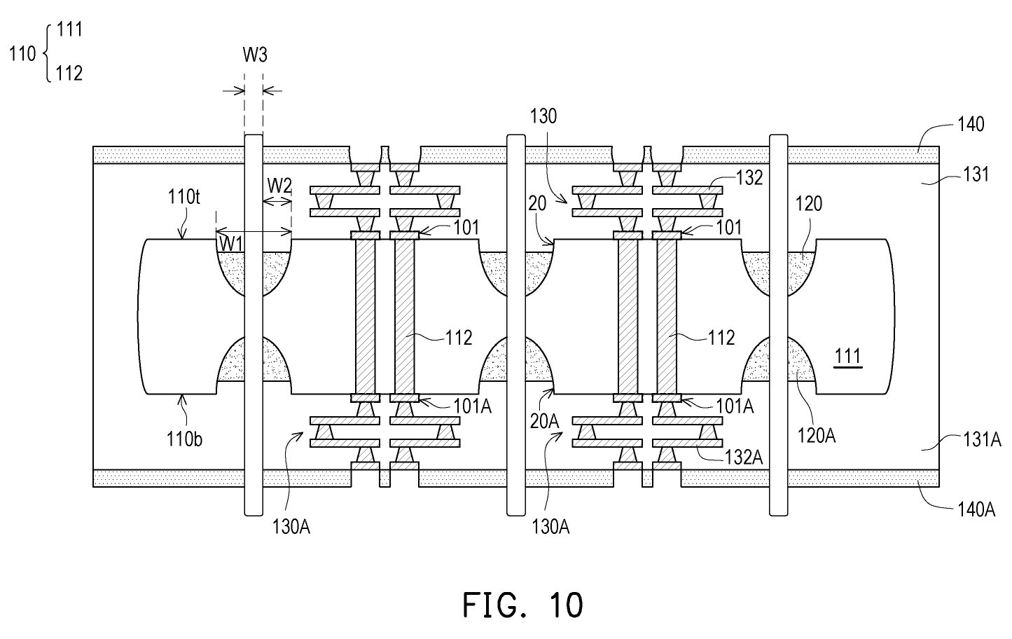

The manufacturing process of the above substrate 100 will be described in FIGS. 2-8, wherein FIGS. 7-8 may be replace by FIGS. 9-10 in alternatively embodiments, the detail is described as below. It must be stated here that the following embodiments continue to use the element reference numerals and part of the content of the above embodiments, in which the same or similar reference numerals are used to denote the same or similar elements, and the description of the same technical content is omitted. The description of the omitted part may be referred to the above embodiments, and the following embodiments will not be redundantly repeated.

Referring to FIG. 2, a plurality of glass core circuit structures 110 are provided, wherein one of the glass core circuit structures 110 includes the glass block 111 and the vertical conductive connectors 112. In some embodiments, the glass block 111 includes Alkali glass, Alkali-free glass, Borosilicate glass, Boro-aluminosilicate glass, Lead Glass, Soda-lime glass or the like. In this stage, outermost of the glass core circuit structures 110 in two sides all include beveling edges, but the disclosure is not limited thereto. In some embodiments, the vertical conductive connectors 112 may be formed by a LIDE (Laser-Induced Deep Etching) process, a metallization process, or other suitable process. For example, metal material (such as Cu, Ti/Cu, Ag, Au, Ni/Au, Ni/Pd, Ni/Pd/Au, or the like) is used in the aforementioned process, but the disclosure is not limited thereto.

In FIG. 2, the conductive patterns 101 are formed on a top surface 120t of the vertical conductive connectors 112, and the conductive patterns 101A are formed on a bottom surface 120b of the vertical conductive connectors 112. In some embodiments, the conductive patterns 101 and the conductive patterns 101A are formed by a plating process or the like, and metal material (such as Cu, Ti/Cu, Ag, Au, Ni/Au, Ni/Pd, Ni/Pd/Au, or the like) is used in the aforementioned process, but the disclosure is not limited thereto.

Referring to FIG. 3, a mask layer 10 is formed on a top surface 110t of the glass core circuit structures 110, and a mask layer 10A is formed on a bottom surface 110b of the glass core circuit structures 110. For example, the mask layer 10 may have openings 11 to expose the top surface 110t of the glass core circuit structures 110, and the mask layer 10A may have openings 11A to expose the bottom surface 110b of the glass core circuit structures 110. In addition, a dicing region DR is formed by a portion of the glass block 111 located between adjacent glass core circuit structures 110, and the portion of the glass block 111 is exposed by the openings 11 and the openings 11A simultaneously.

On the other hand, the conductive patterns 101 may be protected by the mask layer 10, and the conductive patterns 101A may be protected by the mask layer 10A in the following stages. In some embodiments, a width W1 of the dicing region DR is greater than or equal to 100 um, but the disclosure is not limited thereto.

In some embodiments, the mask layer 10 and the mask layer 10A are formed by suitable processes, such as a laser direct image process, a lithography process and, an etching process or a combination thereof, and photosensitive material (such as photoresist or photo imageable dielectric (PID)) is used in the aforementioned process.

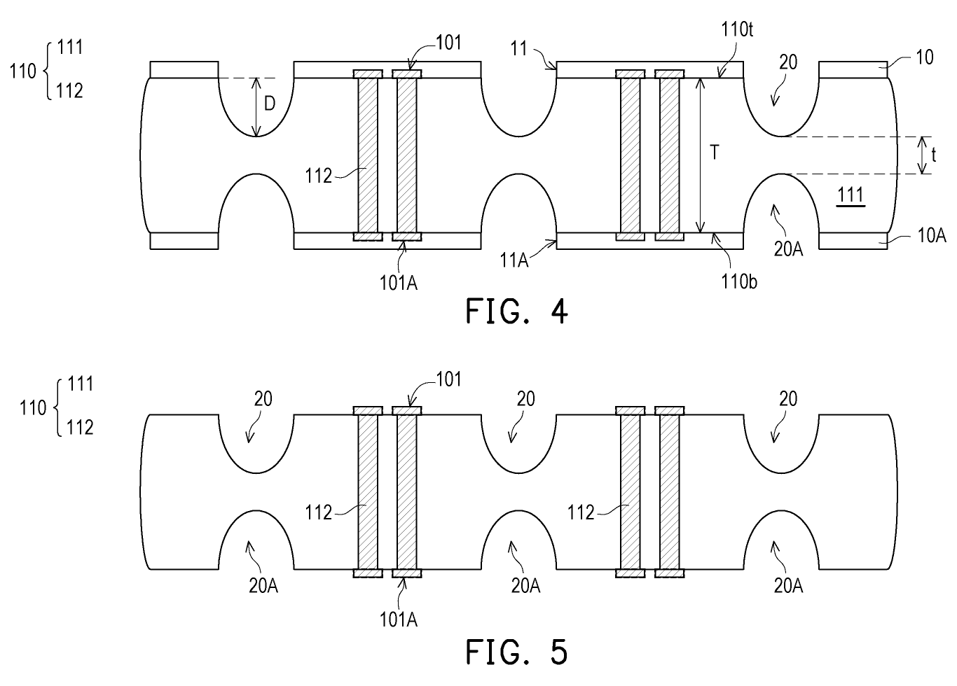

Referring to FIG. 4, a portion of the glass block 111 is removed from the top surface 110t of the glass core circuit structures 110 by the mask layer 10 to form trenches 20, and another portion of the glass block 111 is removed from the bottom surface 110b of the glass core circuit structures 110 by the mask layer 10A to form trenches 20A, wherein neither the trenches 20 nor the trenches 20A penetrates through the glass block 111, such that a remained portion of the glass block 111 is interposed between the trenches 20 and trenches 20A. Referring to FIG. 5, after forming the trenches 20 and the trenches 20A, the mask layer 10 and the mask layer 10A may be removed by suitable process.

In some embodiments, a wet etching process (such as etching with acid etchant or etching with alkaline etchant) is performed to form the trenches 20 and trenches 20A. For example, the etchant includes hydrofluoric acid (HF), ammonium fluoride (NH₄F), or sodium hydroxide (NaOH), but the disclosure is not limited thereto. In some embodiments, a shape of the trenches 20 and trenches 20A in a cross-sectional view may include arc shape, stepped shape, gradual shape, or the like.

In some embodiments, a ratio of a maximum thickness T of the glass block 111 divided a thickness t of the remained glass block 111 interposed between the trenches 20 and trenches 20A*100% (t/T*100%) is greater than or equal to 20%. In addition, a ratio of a depth D of the trenches (such as the trenches 20 or the trenches 20A) divided the maximum thickness T*100% (D/T*100%) is less than or equal to 40%. This specific range may improve reliability problems of the glass block 111 resulting from being too thin or too thick.

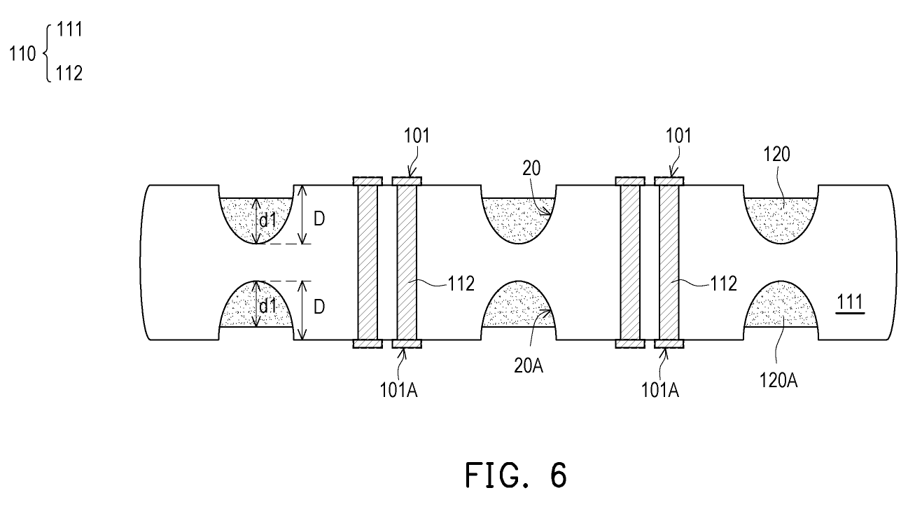

Referring to FIG. 6, the cover layer 120 are formed in the trenches 20, and the cover layer 120A are formed in the trenches 20A. For example, materials of the cover layer 120 and the cover layer 120A may include resin material, such as Ajinomoto Build-up Film (ABF), Photo-imageable dielectric (PID), epoxy-based material (epoxy-based glue), silicone-based material (silicone-based glue), or a combination thereof. In addition, the cover layer 120 and the cover layer 120A may be dispensed into the trenches 20 and the trenches 20A respectively by pneumatic valve, screw-down valve, or piezoelectric valve, and then utilize the vacuum chamber to perform the vacuum degassing, pre-curing and post curing processes in sequence.

In some embodiments, a filled depth d1 of the cover layer (such as the cover layer 120 or the cover layers 120A) may be less than the depth D of the trenches, as shown in FIG. 6, but the disclosure is not limited thereto, the filled depth d1 of the cover layer may be great than or equal to the depth D of the trenches (not shown). In some embodiments, a ratio of the filled depth d1 of the cover layer divided the depth D of the trenches*100% (d1/D*100%) is greater than or equal to 15%.

Referring to FIG. 7, the build-up structure 130 is formed on the top surface 110t of the glass core circuit structures 110, and the build-up structure 130A is formed on the bottom surface 110b of the glass core circuit structures 110, wherein the build-up structure 130 and the build-up structure 130A may have independent conductive structures in this stage, and a set of independent conductive structure exist between adjacent dicing regions DR.

In the present embodiment, the trenches 20 is filled by the insulating layer 131 of the build-up structure 130, and the trenches 20A is filled by the insulating layer 131A of the build-up structure 130A. Here, the build-up structure 130 and the build-up structure 130A may use suitable build-up technology (such as materials and processes), the disclosure is not limited thereto. In FIG. 7, the insulating layer 131 of the build-up structure 130 and the insulating layer 131A of the build-up structure 130A may be further extended to outermost of the glass core circuit structures 110 in two sides and surrounding the glass core circuit structures 110. In unillustrated embodiments, the insulating layer 131 of the build-up structure 130 and the insulating layer 131A of the build-up structure 130A may be not further extended to outermost of the glass core circuit structures 110 in two sides and surrounding the glass core circuit structures 110.

Next, the resist layer 140 is formed on the build-up structure 130, and the resist layer 140A is formed on the build-up structure 130A by suitable deposited process. And then, the bumps 150 are formed in the openings 140a of the resist layer 140 by suitable ball-mounting process. In some embodiments, the bumps 150 may be solder bumps or the like, thereby the resist layer 140 and the resist layer 140A may be solder resist material or the like. In some embodiments, a coin process is performed on the bumps 150, such that top surfaces 150t of the bumps 150 may be flat, as shown in FIG. 7, but the disclosure is not limited thereto, when the coin process is omitted. top surfaces of the bumps are arc-shaped (not shown).

Referring to FIG. 8, a singulation process is performed on the dicing region DR in FIG. 3 to form the substrate 100 including one of the glass core circuit structures 110, a portion of the cover layer 120 and the cover layer 120A, and a portion of the build-up structure 130 and the build-up structure 130A in FIG. 1. Alternatively, the cover layer 160 or the cover layer 160A may be formed, wherein materials of the cover layer 160 or the cover layer 160A includes suitable resin material. In some embodiments, before forming single substrate 100, another singulation process may be perform on the structure to form middle panel type (not shown). In some embodiments, after forming single substrate 100, an AOI test, a package process, or other suitable processes may be performed.

In some embodiments, the singulation process includes a dicing saw process, a laser ablation process, or laser grooving and modification processes, but the disclosure is not limited thereto. In some embodiments, the width W1 of the dicing region DR is equal to 2*a width W2 of remained of the dicing region DR after performing the singulation process* a width W3 (such as dicing saw width or laser beam width).

In FIGS. 7-8, the bumps 150 are formed before performing the singulation process, but the disclosure is not limited thereto, the In FIGS. 9-10, the bumps 150 are not formed before performing the singulation process, that is to say, the bumps 150 are formed after performing the singulation process, for example, the bumps 150 are formed on a single substrate as shown in FIG. 1.

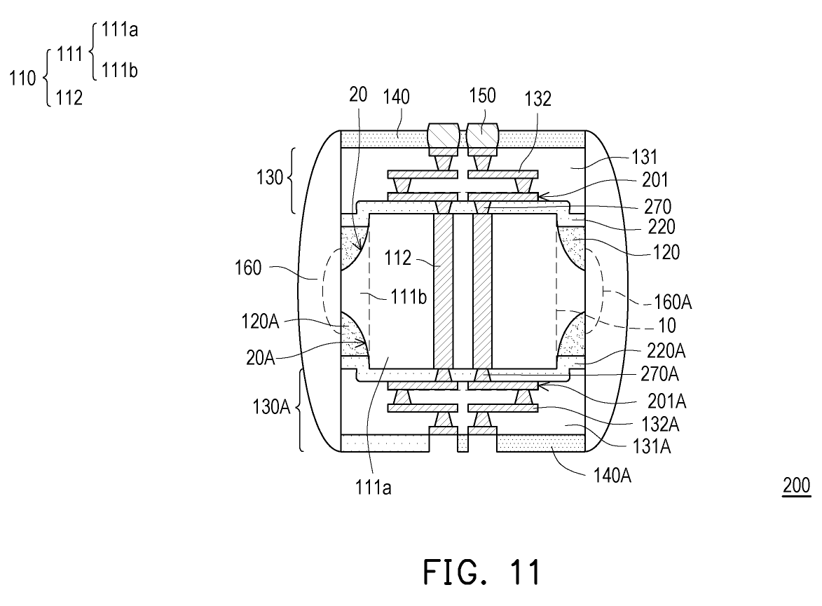

Referring to FIG. 11, similar to FIG. 1, a substrate 200 of FIG. 11 is different from the substrate 100 of FIG. 1 in the following. To be specific, the substrate 200 further includes a cover layer 220 covering the cover layer 120, and a Young’s modulus of the cover layer 220 is less than the Young’s modulus of the insulating layer 130. Accordingly, by designing the Young’s modulus and position of the introduced the cover layer 120 and the cover layer 220, the stress generated during the manufacturing process can be effectively alleviated, thereby the crack (SeWaRe) issue of the glass core circuit structure 110 may be improved. In addition, a Young’s modulus of the cover layer 160 is greater than or equal to the Young’s modulus of the cover layer 220 to further provide protection function.

In the embodiment, the cover layer 220 may be extended on a surface of the glass core circuit structure 110 and a surface of the cover layer 120. In addition, a conductive pattern 201 is spaced from the glass block 111 through the cover layer 220. For example, the substrate 200 further includes conductive vias 270 penetrated through the cover layer 220, and the conductive pattern 201 is electrically connected to the glass core circuit structure 110 through the conductive vias 270. Furthermore, the build-up structure 130 of the substrate 200 is in direct contact with the cover layer 220 and not extended into the trenches 20.

In FIG. 11, the substrate 200 is an approximate symmetric structure, such that the substrate 200 may further include a conductive pattern 201A, a cover layer 220A and conductive vias 270A as shown in the lower part of FIG. 11, such that implementation details of the conductive pattern 201A, the cover layer 220A and the conductive vias 270A may be referred to above description of the conductive pattern 201, the cover layer 220 and the conductive vias 270 respectively. For example, the conductive pattern 201A, the cover layer 220A and the conductive vias 270A may be same as or similar to the conductive pattern 201, the cover layer 220 and the conductive vias 270 respectively.

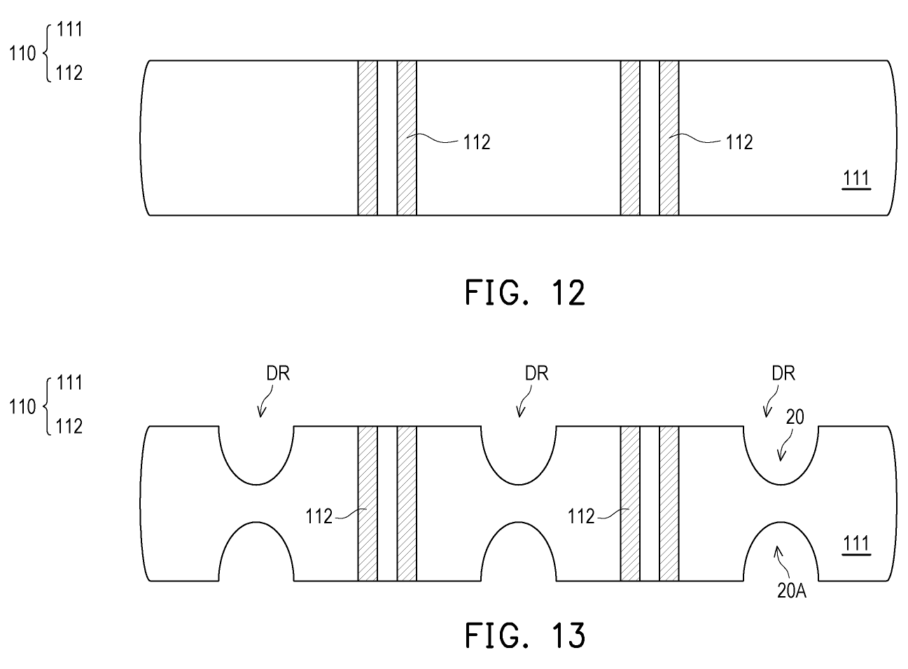

The manufacturing process of the above substrate 200 will be described in FIGS. 12-18, the detail is described as below. It must be stated here that the following embodiments continue to use the element reference numerals and part of the content of the above embodiments, in which the same or similar reference numerals are used to denote the same or similar elements, and the description of the same technical content is omitted. The description of the omitted part may be referred to the above embodiments, and the following embodiments will not be redundantly repeated. It should be noted that the description of FIGS. 9 and 10 may also be applied in this embodiment.

Referring to FIGS. 12, 13, and 14, similar to FIGS. 1, 5 and 6, structures of FIGS. 12, 13 and 14 are different from structures of FIGS. 1, 5 and 6 in the following. To be specific, the conductive patterns 101 and the conductive patterns 101A may be omitted in this stage of the embodiment, such that the conductive patterns 101 and the conductive patterns 101A are not formed on the glass core circuit structures 110 before forming the cover layer 120 and the cover layer 120A, or the conductive patterns 101 and the conductive patterns 101A may be formed first and removed by CMP process.

Referring to FIG. 15, the cover layer 220 is formed on the top surface 120t of the cover layer 120 and the top surface 110t of the glass core circuit structures 110, and the cover layer 220A is formed on the top surface 120At of the cover layer 120A and, and the bottom surface 110b of the glass core circuit structures 110. In the embodiment, the cover layer 220 and the cover layer 220A are fully cover the glass core circuit structures 110. In addition, a thickness d2 of the cover layer (such as the cover layer 220 or the cover layer 220A) on the glass core circuit structures 110 is greater than 1um. In some embodiments, a thickness d3 of the cover layer (such as the cover layer 220 or the cover layer 220A) on the cover layer (such as the cover layer 120 or the cover layer 120A) is greater than or equal to the thickness d2.

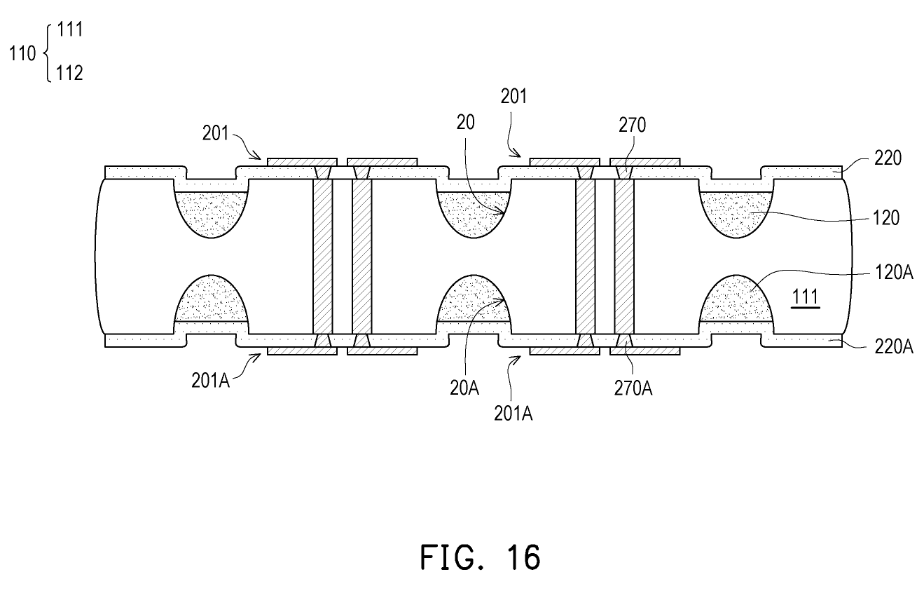

Referring to FIG. 16, the conductive vias 270 are formed in the cover layer 220, and the conductive vias 270A are formed in the cover layer 220A by a plating process or the like. Next, the conductive pattern 201 and the conductive pattern 201A are formed on the conductive vias 270 and the conductive vias 270A respectively by a plating process or the like. In some embodiments, metal material (such as Cu, Ti/Cu, Ag, Au, Ni/Au, Ni/Pd, Ni/Pd/Au, or the like) is used in the aforementioned process, but the disclosure is not limited thereto.

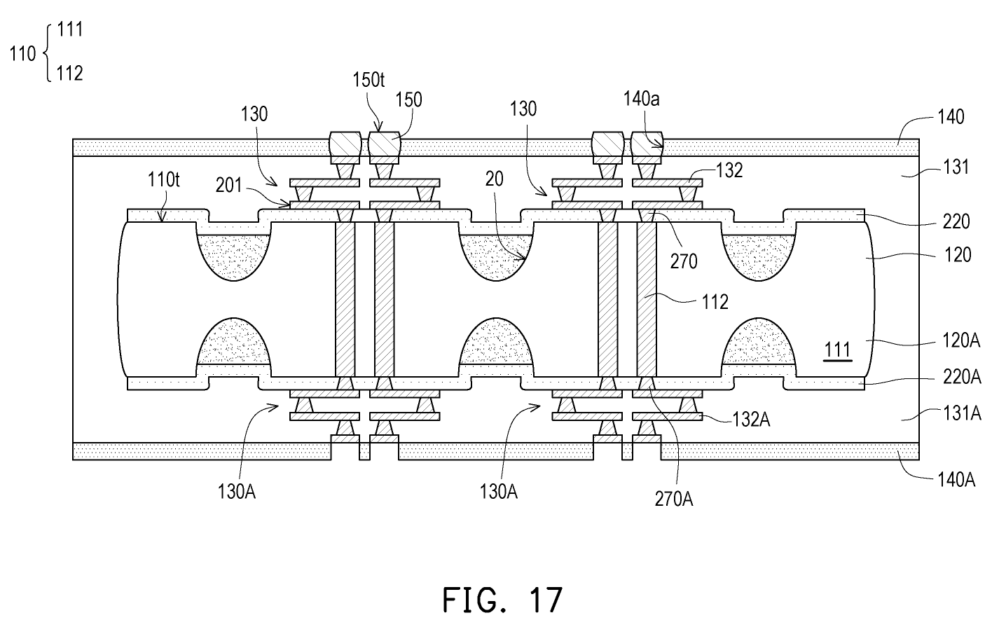

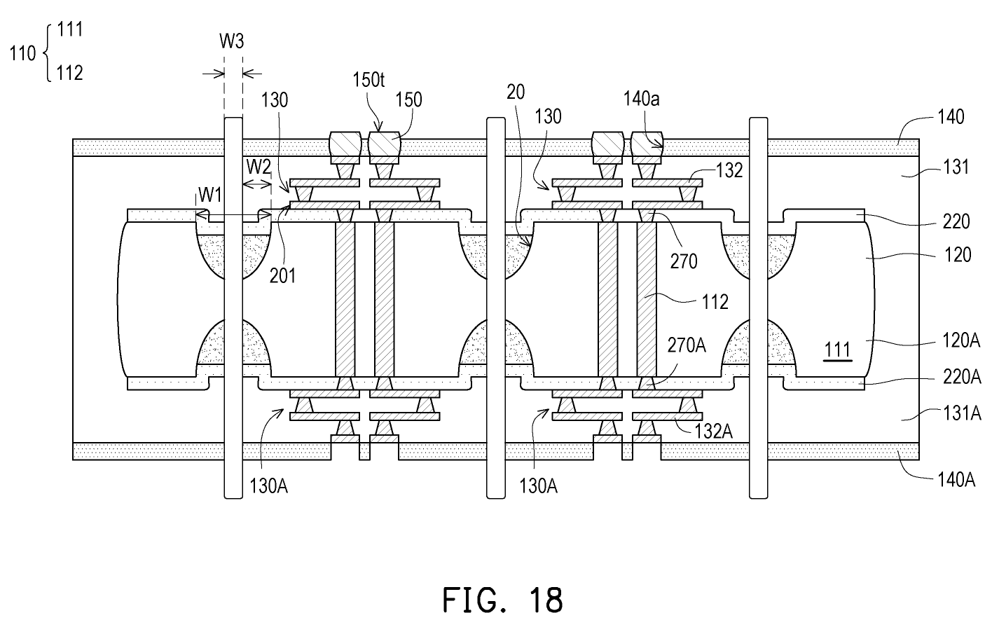

Referring to FIGS. 17-18, similar to FIGS. 7-8, structures of FIGS. 17-18 are different from structures of FIGS. 7-8 in the following. To be specific, the cover layer 220 and the cover layer 220A are introduced, thereby the configuration relationship of the build-up structure 130 and the build-up structure 130A change with the previously introduced layers (the cover layer 220 and the cover layer 220A).

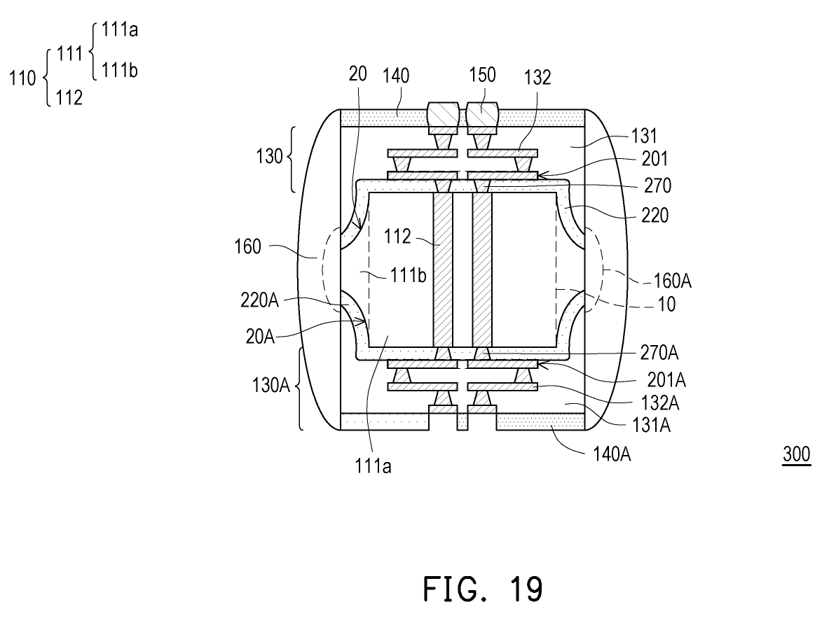

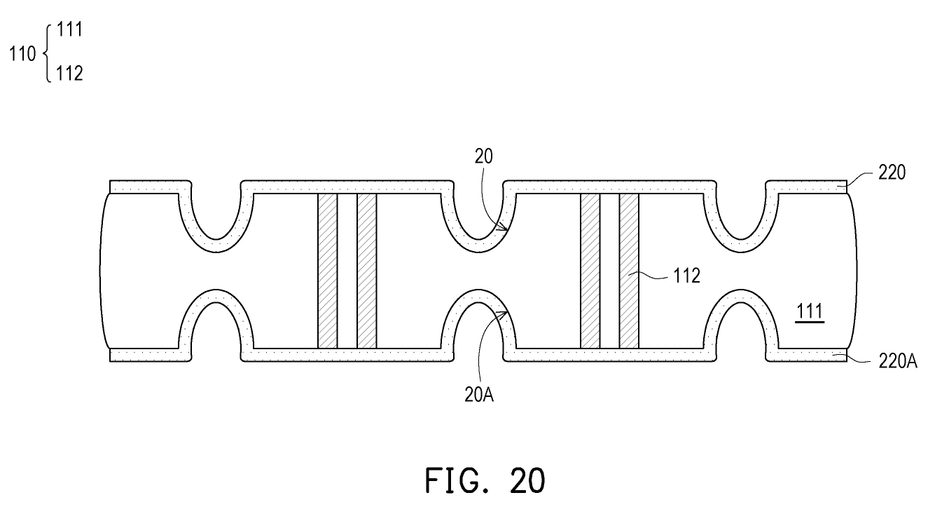

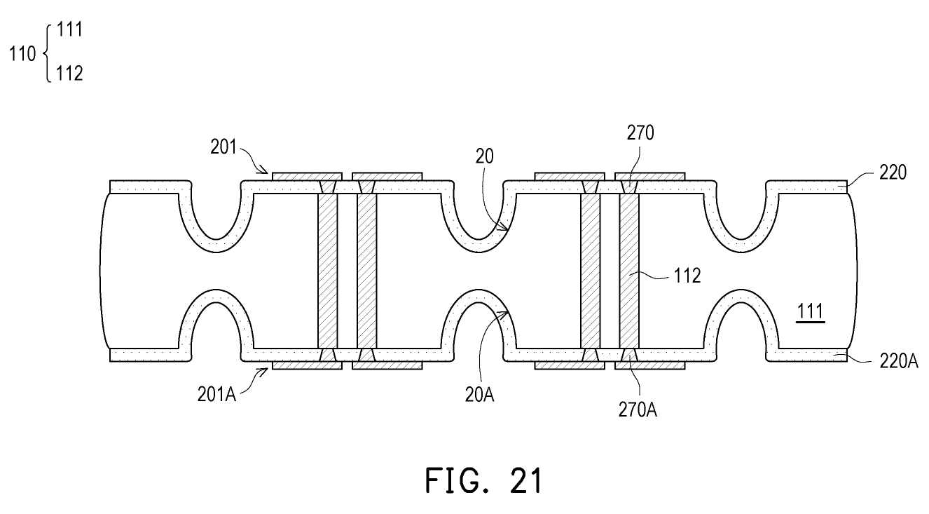

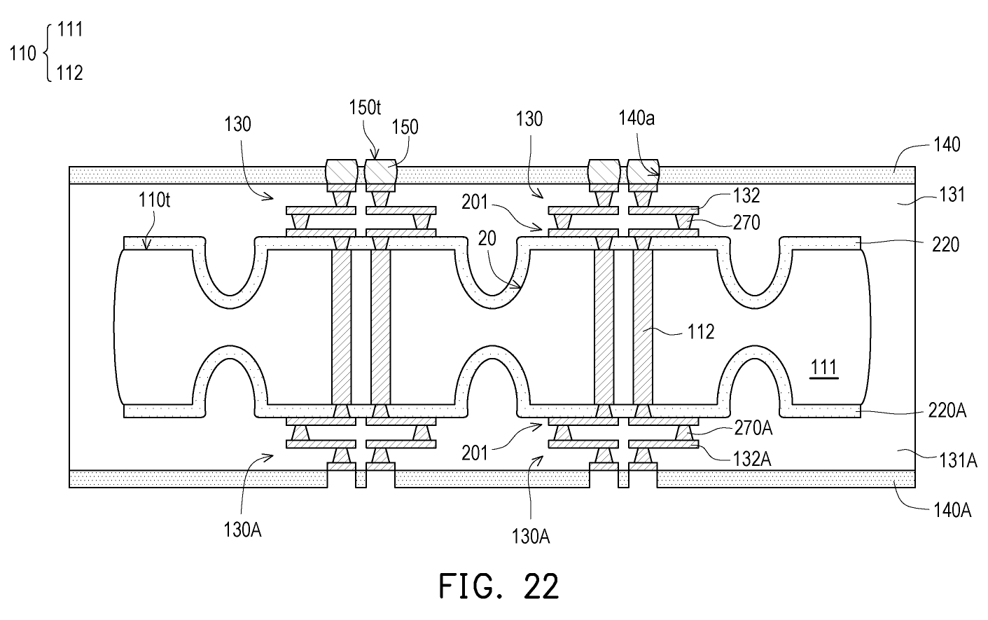

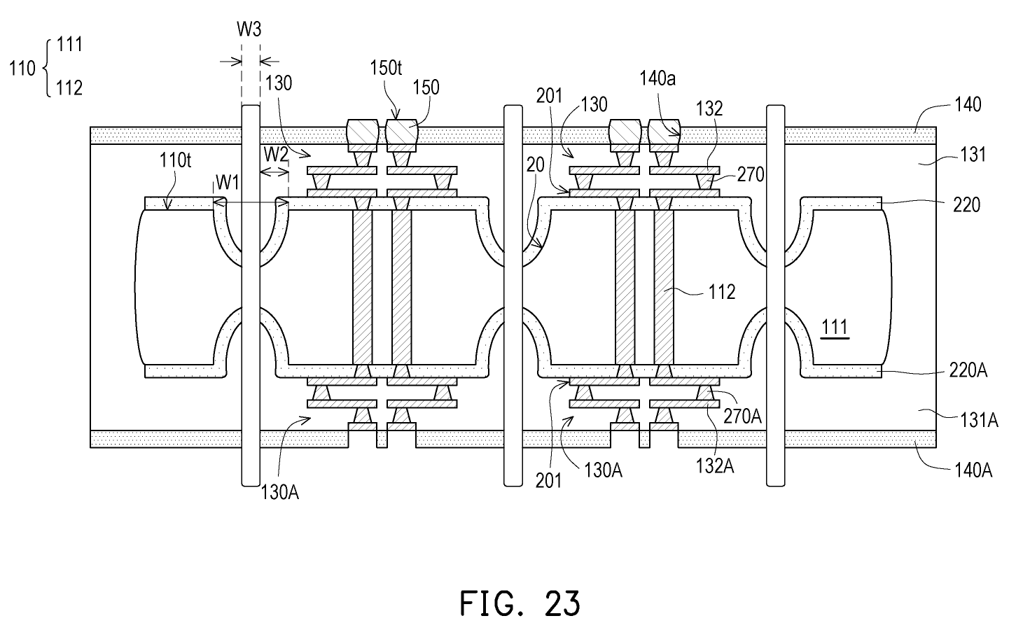

A substrate 300 is illustrated in FIG. 19 and the manufacturing process of the substrate 300 will be described in FIGS. 20-23. It must be stated here that the following embodiments continue to use the element reference numerals and part of the content of the above embodiments, in which the same or similar reference numerals are used to denote the same or similar elements, and the description of the same technical content is omitted. The description of the omitted part may be referred to the above embodiments, and the following embodiments will not be redundantly repeated. It should be noted that the description of FIGS. 9 and 10 may also be applied in this embodiment.

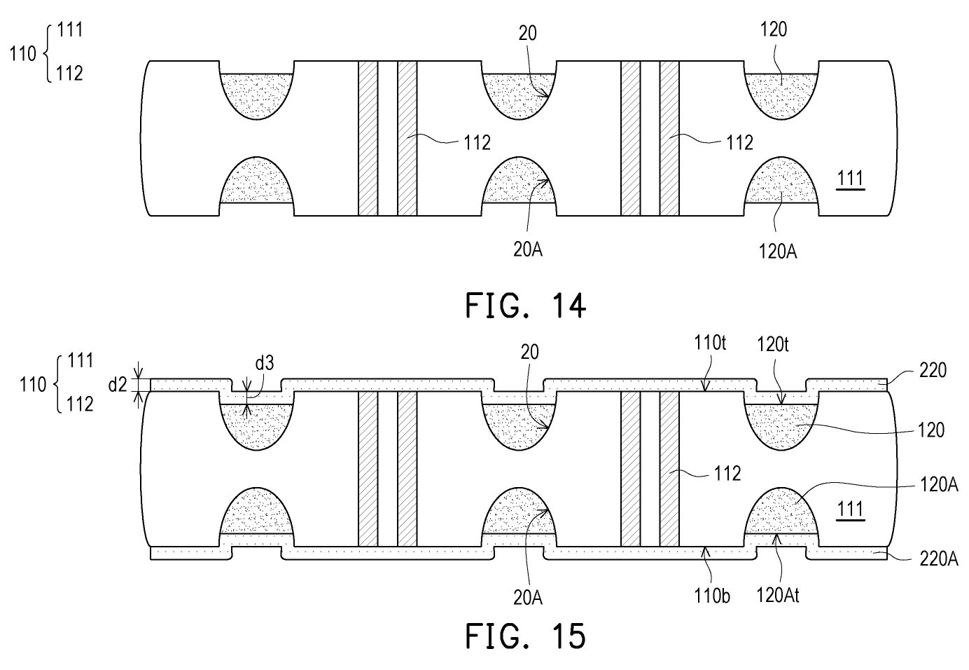

Referring to FIGS. 19-23, the substrate 300 is similar to the substrate 200, the substrate 300 is different from the substrate 200 in the following. To be specific, the cover layer 120 and the cover layer 120A are omitted in this embodiment, while the cover layer 220 and the cover layer 220A are conformally disposed on a surface of the trenches 20 and the trenches 20A directly. In the embodiment, a sidewall of the cover layer 220 and the cover layer 220A have a concave profile. For example, the description of FIG. 14 may be omitted in this embodiment.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A substrate, comprising:
a glass core circuit structure comprising a glass block and a vertical conductive connector;
a first cover layer, embedded in the glass core circuit structure; and
a first build-up structure, disposed on and electrically connected to the glass core circuit structure, wherein the first build-up structure comprises a first insulating layer, and a Young’s modulus of the first cover layer is less than a Young’s modulus of the first insulating layer.

2. The substrate according to claim 1, further comprising:
a second build-up structure, wherein the first build-up structure and the second build-up structure are disposed on opposite surfaces of the glass core circuit structure respectively, the first build-up structure is electrically connected to the second build-up structure through the glass core circuit structure, the second build-up structure comprises a second insulating layer, and the Young’s modulus of the first cover layer is less than a Young’s modulus of the second insulating layer.

3. The substrate according to claim 1, wherein the glass block comprises a first glass block portion and a second glass block portion, a thickness of the first glass block portion is greater than a thickness of the second glass block portion.

4. The substrate according to claim 3, wherein the second glass block portion has a tapered profile in a direction away from the first glass block portion.

5. The substrate according to claim 1, wherein the glass core circuit structure comprises a trench, and the trench is filled by the first cover layer.

6. The substrate according to claim 5, wherein the first cover layer is in direct contact with the first insulating layer and the glass core circuit structure.

7. The substrate according to claim 5, further comprising: a conductive pattern landed on the glass block and the vertical conductive connector.

8. The substrate according to claim 5, further comprising: a second cover layer covering the first cover layer, and a Young’s modulus of the second cover layer is less than a Young’s modulus of the first insulating layer.

9. The substrate according to claim 8, wherein the second cover layer is extended between a surface of the glass core circuit structure and a surface of the first cover layer.

10. The substrate according to claim 8, further comprising: a conductive pattern, wherein the conductive pattern is spaced from the glass block through the second cover layer.

11. The substrate according to claim 8, further comprising:
a third cover layer, disposed on the sidewall of the first cover layer and the sidewall of the glass core circuit structure, and a Young’s modulus of the third cover layer is greater than or equal to the Young’s modulus of the first cover layer and/or the second cover layer.

12. The substrate according to claim 1, wherein the glass core circuit structure comprises a trench, and the first cover layer is conformally disposed on a surface of the trench.

13. The substrate according to claim 12, wherein a sidewall of the first cover layer has a concave profile.

14. The substrate according to claim 1, wherein a sidewall of the first cover layer is aligned with a sidewall of the glass core circuit structure.

15. The substrate according to claim 1, wherein materials of the first cover layer comprise Ajinomoto Build-up Film (ABF), Photo-imageable dielectric (PID), epoxy-based material, silicone-based material, or a combination thereof.

16. A manufacturing method of a substrate, comprising:
providing a plurality of glass core circuit structures, wherein a dicing region is formed by a glass block portion located between adjacent glass core circuit structures;
removing a portion of the glass block portion to form a trench;
forming a cover layer in the trench;
forming a build-up structure on the plurality of glass core circuit structures, wherein the build-up structure is electrically connected to the glass core circuit structures, and a Young’s modulus of the cover layer is less than a Young’s modulus of an insulating layer of the build-up structure; and
performing a singulation process on the dicing region to form the substrate comprising one of the glass core circuit structures, a portion of the cover layer, and a portion of the build-up structure.

17. The manufacturing method of a substrate according to claim 16, further comprising:
forming a plurality of bump on the build-up structure before performing the singulation process.

18. The manufacturing method of a substrate according to claim 16, further comprising:
forming a plurality of bump on the build-up structure after performing the singulation process.

19. The manufacturing method of a substrate according to claim 16, further comprising:
forming a plurality of conductive patterns on the glass core circuit structures before forming the trench.

20. The manufacturing method of a substrate according to claim 16, further comprising:
forming a plurality of conductive patterns on the glass core circuit structures after forming the cover layer.
